(19) United States
(12) Patent Application Publication
(10) Pub. No.: US 2010/0136331 A1
(43) Pub. Date: Jun. 3, 2010

(54) TRANSPARENT BARRIER FILM AND METHOD FOR PRODUCING THE SAME

(75) Inventors: Matthias Fahland, Dresden (DE); Tobias Vogt, Kurort Johnsdorf (DE); Nicolas Schiller, Stolpen OT Helmsdorf (DE); John Fahlteich, Dresden (DE); Waldemar Schoenberger, Dresden (DE)

Correspondence Address: GREENBLUM & BERNSTEIN, P.L.C., 1950 ROLAND CLARKE PLACE, RESTON, VA, 20191, US

(73) Assignee: FRAUNHOFER-GESELLSCHAFT ZUR FOERDERUNG DER ANGEWANDTEN FORSCHUNG E.V., Muenchen (DE)

(21) Appl. No.: 12/597,696

(22) PCT Filed: Mar. 3, 2008
(86) PCT No.: PCT/EP2008/001694

§ 371 Date: Oct. 26, 2009

(30) Foreign Application Priority Data
Apr. 27, 2007 (DE) 10 2007 019 994.7

(51) Int. Cl. B32B 5/00; B32B 9/00; C23C 26/00; C23C 14/34

(52) U.S. Cl. 428/336; 428/689; 428/702; 428/688; 427/294; 204/192.14; 204/192.13; 427/248.1

(57) ABSTRACT

The invention relates to a transparent barrier film, comprising a transparent thermoplastic film and at least one permeation barrier layer, wherein the permeation barrier layer comprises a chemical compound of the elements zinc, tin and oxygen, and the mass fraction of zinc is 5% to 70%. Furthermore, the invention relates to a method for the production of a barrier film of this type.

The invention relates to a thermoplastic barrier film with an excellent permeation barrier to oxygen and water vapor with at the same time high transparency for light in the visible spectral range. The invention further relates to a method for producing a film of this type.

### PRIOR ART

The use of plastic films as packaging material or as a protective film for sensitive objects is very widespread. There is often a requirement that these plastic films not only have to provide a mechanical protection or a mechanical confinement, but also at the same time these films should also achieve a blocking action with respect to gases. This blocking action is also referred to below as a permeation barrier. With the blocking action of barrier films, it is often particularly important that this blocking action is achieved with respect to the gases oxygen and water vapor contained in the atmosphere. These gases in contact with objects can cause various chemical reactions, which are often undesirable with respect to a material to be protected. The use of barrier films is widespread in the packaging of foodstuffs. The water vapor transmission rate variable is known as a feature for the quality of a permeation barrier. For example, a film of polyethylene terephthalate (PET) with a thickness of 125 μm has a water vapor transmission rate of approx. 8 g/m² d (wherein the “d” in the unit stands for “day” i.e., for 24 hours). This value is dependent on the thickness of the film. However, in many applications even much lower permeation values are required. For example, it is necessary to achieve a value of approx. 1 g/m² d for food packaging.

It is known that such values can be achieved if a multilayer barrier film is used. One ply is hereby the plastic film itself, a second ply is realized, for example, through a thin layer on the film which achieves a higher permeation effect. A layer of this type can be of aluminum, for example. Often a requirement is that a barrier film must not only have a permeation barrier, but at the same time it must also still be transparent. Transparency hereby means that this film has a transmission of at least 70% in the visible spectral range, that is, between 380 nm and 780 nm light wave length. The requirement for transparency applies in particular when a barrier film is to be used for the encapsulation of optoelectronic devices, such as solar cells or display elements. The combination of a plastic film with a thin metal layer is unsuitable in the case of this type of requirement.

It is known that a water vapor transmission rate of approx. 1 g/m² d and below can be achieved by a combination of a plastic film with an oxide layer, wherein the exact value depends on the coating method used as well as on the coating material, since the oxides of different elements are not equally suitable for layers with permeation effect. Thus, it is known, for example, that a good blocking action cannot be achieved with TiO₂ layers, whereas oxide layers of the element aluminum form a very good permeation barrier (N. Schiller et al., Barrier Coatings on Plastic Web, 44^{th} Annual Technical Conference Proceedings, 2001). Furthermore, layers of Si₃N₄ also have a very good permeation barrier.

However, the materials Si₃N₄ and aluminum oxide tend to form cracks after being applied on flexible plastic webs, which has a negative effect on the barrier effect achieved. The use of barrier films of this type is likewise restricted thereby. This fact is not only a disadvantage in the packaging of foodstuffs, but also when sensitive technical goods are to be protected. Goods of this type can be, for example, solar cells (requirement: water vapor transmission rate 10⁻³ g/m² d), thin-film batteries on a lithium basis (requirement: water vapor transmission rate 2×10⁻⁴ g/m² d) or organic light-emitting diodes (requirement: water vapor transmission rate 10⁻⁶ g/m² d).

Although in general it holds true that the blocking action of a barrier layer increases with increasing layer thickness, no further increase in the barrier action can be achieved from a certain layer thickness due to the crack formation, in particular with aluminum oxide layers. Thus, for example, with an Al₂O₃ layer with a layer thickness of approx. 100 nm a value of 0.09 g/m² d is achieved regarding the barrier action. With a further increase in layer thickness, a noticeable increase with respect to the barrier action is no longer recorded.

Various improvements have been carried out with known barrier films. This applies in particular to barrier layers with increased permeation blocking action. Thus, for example, a SiO₂ layer with a gradient with respect to the material properties is known from EP 0 311 432 A2. A mechanical adjustment of the permeation block to the plastic film and thus a better mechanical ruggedness are to be achieved therewith.

Another approach lies in a multilayer structure of a layer system, in which an inorganic layer and an organic layer are applied alternately. An approach of this type is presented in J. D. Affinito et al., Thin Solid Films 290-291 (1996), p. 63-67, wherein Al₂O₃ is used as an inorganic layer with high blocking action.

In DE 10 2004 005 313 A1 an inorganic layer is combined with a second layer, which is applied in a special magnetron-based PECVD method. Al₂O₃ as an inorganic layer also forms one of the possible embodiments in this case.

All of the known approaches have in common that a high blocking action is achieved in that at least one material with high blocking action is deposited on a plastic film by means of a corresponding coating technology. However, the materials used thereby, in particular Al₂O₃, tend to form cracks under mechanical stress, which limits their use.

### OBJECT

The technical object of the invention is therefore to create a transparent barrier film and a method for the production thereof, by means of which the disadvantages of the prior art can be overcome. In particular, the barrier film is to have very good blocking properties with respect to oxygen and water vapor and to be less susceptible to crack formation under mechanical stress.

The solution to this technical problem is shown by the subject matters with the features of claims 1 and 8. Further advantageous embodiments of the invention are shown by the dependent claims.

A transparent barrier film according to the invention comprises a transparent thermoplastic film and at least one permeation barrier layer. The permeation barrier layer thereby comprises a chemical compound of the elements zinc, tin and oxygen, wherein the mass fraction of zinc is 5% to 70%.

It was determined that a thin layer of zinc tin oxide is present as an amorphous material. It thus has a lower packing density than comparable microcrystalline materials, such as, for example, pure zinc oxide. Nevertheless, the mixed oxide of an alloy of zinc and tin is characterized by a very marked permeation blocking action. Furthermore, it was surprisingly shown that, compared to aluminum oxide, layers of zinc tin oxide have a very much improved flexibility and a lower tendency to cracking. Thus with an increase in the thickness of a zinc tin oxide layer over 100 nm, it was possible to achieve a further improvement of the barrier properties.

A permeation barrier layer of a barrier film according to the invention can therefore be embodied in a broad layer thickness range of 20 nm to 1000 nm. However, very good barrier properties are already achieved in a layer thickness range of 50 nm to 300 nm.

In addition to a thermoplastic film and a permeation barrier layer, a barrier film according to the invention can comprise further layers. Thus, for example, a further layer which comprises the elements silicon and carbon and has a carbon mass fraction of 1% to 10%, can be deposited between the film and the permeation barrier layer. A layer of this type serves on the one hand as a smoothing layer and on the other hand causes an equalization or a continuous transition of the mechanical properties of the film and those of the permeation barrier layer.

However, similar effects can also be achieved without an intermediate layer of this type, when the permeation barrier layer on the film is embodied with a gradient such that the permeation barrier layer on the side facing towards the film has a carbon mass fraction of up to 5%.

In another embodiment of the invention, a transparent barrier film comprises an electrically conductive layer with a specific resistance of less than 2×10⁻³ Ωcm. A barrier film of this type with a functional layer of this type can be used at the same time as a transparent electrode. There is also the possibility that a barrier film according to the invention comprises a layer stack in which permeation barrier layers, smoothing layers and/or functional layers are deposited alternately on a film.

In a method according to the invention for producing a transparent barrier film, comprising a transparent thermoplastic film and at least one permeation barrier layer, the permeation barrier layer is deposited as a chemical compound of the elements zinc, tin and oxygen by means of a vacuum coating process.

The permeation barrier layer is thereby deposited with a thickness of 20 nm to 1000 nm and preferably in a range of 50 nm to 300 nm.

Magnetron sputtering, for example, is suitable as a vacuum coating method. An alloy of zinc and tin as target is hereby sputtered, wherein the sputtering process is carried out in the presence of the reactive gas oxygen.

In order to be able to achieve uniform barrier properties on the entire surface of a film, it is also necessary that a permeation barrier layer with constant layer thickness is deposited on the entire film surface. The thickness of a deposited permeation barrier layer can be advantageously adjusted via the supply of the reactive gas oxygen into the vacuum work chamber. As is known, an increase in oxygen during a reactive sputtering process leads to an increased formation of reaction products on the target to be sputtered, which in turn leads to a reduction in the sputtering rate. The layer increase of a permeation barrier layer can thus be adjusted via the supply of the reactive gas.

In a preferred embodiment the oxygen inlet into the vacuum work chamber is therefore controlled by means of a control loop. It is advantageous hereby in turn if a controlled variable for controlling the oxygen inlet is determined from the optical emission spectrum of the sputtering plasma.

The quotient of an emission line of zinc or tin and an emission line of the inert gas used, for example, can be determined as a controlled variable.

### EXEMPLARY EMBODIMENT

The invention is explained in more detail below based on a preferred exemplary embodiment. The Figs. show:

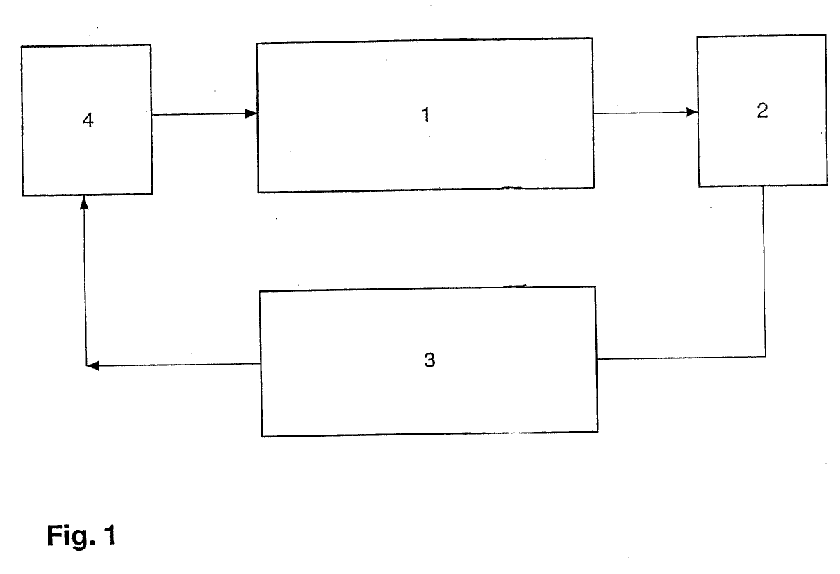

FIG. 1A diagrammatic representation of a control loop for adjusting the oxygen inflow during reactive deposition of a ZnSnOₓ layer by magnetron sputtering as a function of values that are obtained from the intensity of two spectral lines of the magnetron plasma;

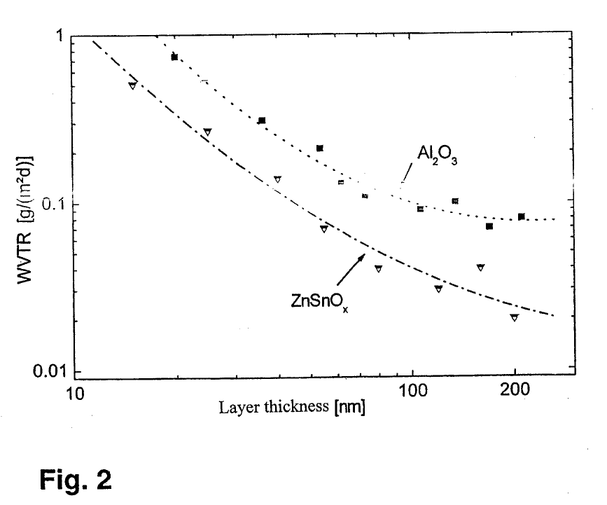

FIG. 2 A graphic representation of the dependence of the water transmission rate on the layer thickness of a permeation barrier layer of Al₂O₃ and a permeation blocking layer of ZnSnOₓ.

A permeation barrier layer of zinc tin oxide is deposited on a thermoplastic plastic film of polyethylene terephthalate (PET) by means of a reactive sputtering method. For this purpose a target of a zinc tin alloy is sputtered in the presence of the inert gas argon and with the supply of the reactive gas oxygen. It is known that the degree of the coverage of the target with reaction products and thus the deposition rate/layer thickness and the layer composition can be adjusted via the supply of the reactive gas oxygen. FIG. 1 shows diagrammatically a control loop by means of which the permeation barrier layer can be deposited with a constant layer thickness and thus with constant barrier properties.

In a vacuum chamber 1 for carrying out the sputtering process, an intensity value of a spectral line of zinc and an intensity value of a spectral line of argon are determined by means of a spectrometer 2, transferred to an evaluation device 3 and therein a quotient of the two intensity values is formed. A control signal is produced from the comparison of the quotient actual value determined in this manner with a predetermined desired value, which control signal activates an oxygen inlet valve 4 and readjusts the oxygen supply into the vacuum chamber 1 such that the determined quotient actual value is matched to the predetermined desired value.

In FIG. 2 the permeation blocking action of a barrier film with a barrier layer of zinc tin oxide, which was deposited according to the method according to the invention, is shown graphically as a function of the layer thickness of the barrier layer. The water vapor transmission rate is thereby plotted on the y-axis as a measure of the permeation barrier action. The respective pairs of values with respect to layer thickness and water vapor transmission rate are shown as small triangles and a fitted curve resulting therefrom is shown as a dash-dot line.

The permeation barrier action of a barrier film with identical film substrate, but an Al₂O₃ layer according to the prior art is also shown in FIG. 2 as a function of the layer thickness of the Al₂O₃ layer. The associated pairs of values are shown as small squares and a fitted curve resulting therefrom as a dotted line. It can be seen from FIG. 2 that a barrier film according to the invention with the same thickness has a better permeation barrier action than a barrier film with an Al₂O₃ layer according to the prior art. It is likewise discernible that from a layer thickness of approx. 100 nm no significant improvement in the blocking action can be achieved with the Al₂O₃ layer, but with the barrier film according to the invention an increase in the layer thickness over 100 nm still causes a significant improvement in the barrier properties, from which it can be deduced that a barrier film according to the invention has a lower tendency to cracking than known barrier films with Al₂O₃ layer.

1. Transparent barrier film, comprising a transparent thermoplastic film and at least one permeation barrier layer, characterized in that the permeation barrier layer comprises a chemical compound of the elements zinc, tin and oxygen, wherein the mass fraction of zinc is 5% to 70%.

2. Barrier film according to claim 1, characterized in that the permeation barrier layer is embodied with a thickness of 20 nm to 1000 nm.

3. Barrier film according to claim 2, characterized in that the permeation barrier layer is embodied with a thickness of 50 nm to 300 nm.

4. Barrier film according to claim 1, characterized in that the permeation barrier layer on the side facing towards the thermoplastic film has a carbon mass fraction of up to 5%.

5. Barrier film according to claim 1, characterized in that the barrier film comprises at least one further layer.

6. Barrier film according to claim 5, characterized in that a first further layer is electrically conductive and has a specific resistance of less than 2×10⁻³ Ωcm.

7. Barrier film according to claim 5, characterized in that a second further layer comprises the elements silicon and carbon, wherein the carbon mass fraction is 1% to 10%.

8. Method for producing a transparent barrier film, comprising a transparent thermoplastic film and at least one permeation barrier layer, characterized in that the permeation barrier layer is deposited as a chemical compound of the elements zinc, tin and oxygen by means of a vacuum coating process.

9. Method according to claim 8, characterized in that the permeation barrier layer is deposited with a thickness of 20 nm to 1000 nm.

10. Method according to claim 9, characterized in that the permeation barrier layer is deposited with a thickness of 50 nm to 300 nm.

11. Method according to claim 8, characterized in that the permeation barrier layer is deposited by sputtering.

12. Method according to claim 11, characterized in that a target comprising an alloy of zinc and tin is atomized with the intake of the reactive gas oxygen.

13. Method according to claim 12, characterized in that the oxygen inlet is controlled by means of a control loop, in which a controlled variable is determined from the optical emission spectrum of the sputtering plasma.

14. Method according to claim 13, characterized in that the quotient of an emission line of zinc or tin and an emission line of the inert gas used is determined as a controlled variable.
